(19) United States
(12) Patent Application Publication
(10) Pub. No.: US 2023/0162994 A1
(43) Pub. Date: May 25, 2023

(54) APPARATUS FOR TREATING SUBSTRATE

(71) Applicant: SEMES CO., LTD., Cheonan-si (KR)

(72) Inventor: JAE SEONG LEE, Hwaseong-si (KR)

(73) Assignee: SEMES CO., LTD., Cheonan-si (KR)

(21) Appl. No.: 17/990,715

(22) Filed: Nov. 20, 2022

(30) Foreign Application Priority Data
Nov. 22, 2021 (KR) 10-2021-0161391

(51) Int. Cl. H01L 21/67; C23C 16/44; H01L 21/687; H01L 21/02

(52) U.S. Cl. CPC H01L 21/6704; C23C 16/4412; H01L 21/6875; H01L 21/02101

(57) ABSTRACT

The inventive concept provides a substrate treating apparatus. The substrate treating apparatus includes a chamber body having a top body and a bottom body which combine to provide a treating space therein; a substrate support unit configured to support a substrate at the treating space; a fluid supply unit configured to supply a treating fluid to the treating space; a fluid exhaust line for exhausting the treating fluid from the treating space; and a guide member provided to surround a periphery of the substrate supported by the substrate support unit.

### CROSS-REFERENCE TO RELATED APPLICATIONS

A claim for priority under 35 U.S.C. § 119 is made to Korean Patent Application No. 10-2021-0161391 filed on Nov. 22, 2021, in the Korean Intellectual Property Office, the entire contents of which are hereby incorporated by reference.

### BACKGROUND

Embodiments of the inventive concept described herein relate to a substrate treating apparatus.

In order to manufacture a semiconductor device, a desired pattern is formed on a substrate such as a wafer through various processes on the substrate such as a photolithography process, an etching process, an ashing process, an ion implantation process, and thin film deposition process. Various treating liquids and treating gases are used for each process, and particles and process by-products are generated during the process. In order to remove these particles and process by-products from the substrate, a cleaning process is performed before and after each process.

A conventional cleaning process treats the substrate with a chemical and a rinsing liquid. Afterwards, a drying treatment is performed. An embodiment of the drying treatment includes a rotary drying process in which the substrate is rotated at a high speed to remove the rinsing liquid remaining on the substrate. However, there is a concern that this rotary drying method may collapse a pattern formed on the substrate.

Thus, recently a supercritical drying process is used for supplying an organic solvent such as an isopropyl alcohol (IPA) onto the substrate to replace a rinsing liquid remaining on the substrate with an organic solvent having a low surface tension, and then supplying a treating fluid (e.g., carbon dioxide) in a supercritical state onto the substrate to remove an organic solvent remaining on the substrate. In the supercritical drying process, the drying gas is supplied to a process chamber with a sealed inside, and the drying gas is heated and pressurized. Both a temperature and a pressure of the drying gas rise above a critical point, and the drying gas phase changes to the supercritical state.

In the substrate treating apparatus that performs the supercritical drying process, there is a substrate guide for mounting the substrate transferred in a supercritical treating space, and an outer space of the substrate is empty without any special function other than this substrate guide. In addition, due to the substrate guide, a shapely asymmetry occurs, resulting in a poor uniformity of an airflow.

### SUMMARY

Embodiments of the inventive concept provide a substrate treating apparatus for efficiently treating a substrate.

Embodiments of the inventive concept provide a substrate treating apparatus for reducing a process time and improving a productivity.

Embodiments of the inventive concept provide a substrate treating apparatus for improving a uniformity of a flow.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber body having a top body and a bottom body which combine to provide a treating space therein; a substrate support unit configured to support a substrate at the treating space; a fluid supply unit configured to supply a treating fluid to the treating space; a fluid exhaust line for exhausting the treating fluid from the treating space; and a guide member provided to surround a periphery of the substrate supported by the substrate support unit.

In an embodiment, the substrate support unit supports a first edge region of the substrate at the treating space, and the guide member is provided to surround a second edge region which is different from the first edge region of the substrate supported by the substrate support unit.

In an embodiment, the guide member includes a guide block in an arc shape supported by a bottom surface of the bottom body, and which is positioned at an outside of the second edge region when seen from above.

In an embodiment, the substrate support unit includes: fixing rods which are fixedly installed to a bottom surface of the top body to downwardly protrude from the bottom surface of the top body; and a holder which extends in a horizontal direction with respect to the ground from a bottom end of the fixing rod, and which is provided to support a bottom surface of the first edge region of the substrate.

In an embodiment, the guide block includes support protrusions at a bottom surface to be spaced apart from the bottom surface of the bottom body.

In an embodiment, the guide block includes through holes which the treating fluid passes through.

In an embodiment, the treating space is divided into a top space and a bottom space with respect to the substrate supported by the substrate support unit, and the guide block includes top surface positioned at the top space and a bottom surface positioned at the bottom space.

In an embodiment, the through hole includes: a first inlet connected to the top space; a second inlet connected to the bottom space; and a connection path connecting the first inlet and the second inlet.

In an embodiment, the guide block is provided to be spaced apart from an edge region of the substrate placed on the substrate support unit, and further includes a block driving unit for sliding the guide block to adjust a gap between the guide block and the edge region of the substrate.

In an embodiment, the substrate treating apparatus further includes: a lifting/lowering member for lifting and lowering any one of the top body and the bottom body with respect the other one to be spaced apart to an open position or a close position; and a clamping unit configured to clamp the top body and the bottom body positioned at the close position.

In an embodiment, the treating space is divided into a top space and a bottom space with respect to the substrate supported on the substrate support unit, and the top body includes: a first supply channel connected to the fluid supply unit to supply the treating fluid to the top space, and the bottom body includes: an exhaust channel connected to the fluid exhaust line to exhaust the treating fluid from the treating space.

In an embodiment, the process fluid is a supercritical fluid phase.

The inventive concept provides a substrate treating apparatus. The substrate treating apparatus includes a chamber body defining a treating space for treating a substrate, the chamber body including a first chamber body and a second chamber body provided below the first chamber body to be relatively movable with respect to the first chamber body; a lifting/lowering member for lifting and lowering any one of the first chamber body and the second chamber body with respect to the other one to be spaced apart to an open position or a close position; a clamping body for clamping the first chamber body and the second chamber body, if the first chamber body and the second chamber body are in close contact in a close position; and a substrate support unit configured to support the substrate at the treating space; a fluid supply unit configured to supply a treating fluid to the treating space; a fluid exhaust line for exhausting the treating fluid from the treating space; and a guide member provided to surround a periphery of the substrate which is supported by the substrate support unit.

In an embodiment, the substrate support unit supports a first edge region of the substrate at the treating space, and the guide member is provided to surround a second edge region which is different from the first edge region of the substrate supported on the substrate support unit.

In an embodiment, the substrate support unit includes: fixing rods which are fixedly installed to a bottom surface of the first chamber body to downwardly protrude from the bottom surface of the first chamber body; and a holder which extends in a horizontal direction with respect to the ground from a bottom end of the fixing rod, and which is provided to support a bottom surface of the first edge region of the substrate, and the guide member includes a guide block in an arc shape supported by the second chamber body, and which is positioned at an outside of the second edge region when seen from above.

In an embodiment, a passage is provided between the guide block and the second chamber body at which the treating fluid passes through.

In an embodiment, the guide block includes through holes which the treating fluid passes through.

In an embodiment, the treating space is divided into a top space and a bottom space with respect to the substrate supported by the substrate support unit, and the through hole includes: a first inlet connected to the top space; a second inlet connected to the bottom space; and a connection path connecting the first inlet and the second inlet.

The inventive concept provides a substrate treating apparatus for treating a substrate by using a treating fluid in a supercritical state. The substrate treating apparatus includes a chamber body having a top body and a bottom body which combine to provide a treating space therein; a substrate support unit configured to support the substrate at the treating space; a lifting/lowering member for lifting and lowering any one of the top body and the bottom body with respect the other one to be spaced apart to an open position or a close position; a clamping unit configured to clamp the top body and the bottom body positioned at the close position; a fluid supply unit configured to supply the treating fluid to the treating space; a fluid exhaust line for exhausting the treating fluid from the treating space; and a guide block provided to surround a periphery of the substrate supported by the substrate support unit, and wherein the substrate support unit is provided at the top body to support a first edge region of the substrate at the treating space, and the guide member is provided to surround a second edge region which is different from the first edge region of the substrate supported by the substrate support unit.

In an embodiment, the guide block includes: support protrusions at a bottom surface of the guide block so the treating fluid passes between the guide block and a bottom surface of the bottom body; and through holes which the treating fluid passes through.

According to an embodiment of the inventive concept, a process time may be reduced and a productivity may be improved.

According to an embodiment of the inventive concept, a uniformity of a flow may be improved.

According to an embodiment of the inventive concept, a characteristic of an inner flow may be adjusted by changing a form of a guide member.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 illustrates an embodiment of a liquid treating chamber of FIG. 1.

FIG. 3 illustrates an embodiment of a drying chamber of FIG. 1.

FIG. 4 schematically illustrates a state of which the top body and the bottom body are positioned in the closed position of FIG. 3.

FIG. 5 schematically illustrates an embodiment of a drying chamber of FIG. 3.

FIG. 6 illustrates a state in which a top body and a bottom body of FIG. 5 are positioned in a close position.

FIG. 7 illustrates a support member and a guide member of FIG. 3.

FIG. 8 is a top view of the support member and the guide member of FIG. 7.

FIG. 9 is an enlarged view illustrating the support member and the guide member while the top body and the bottom body is positioned in the closed position.

FIG. 10 is a partial cut view of a modified embodiment of the guide member.

FIG. 11 in an enlarged view illustrating the guide member while the top body and the bottom body is positioned in the closed position.

FIG. 12 illustrates another modified embodiment of the guide block.

FIG. 13 illustrates another embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

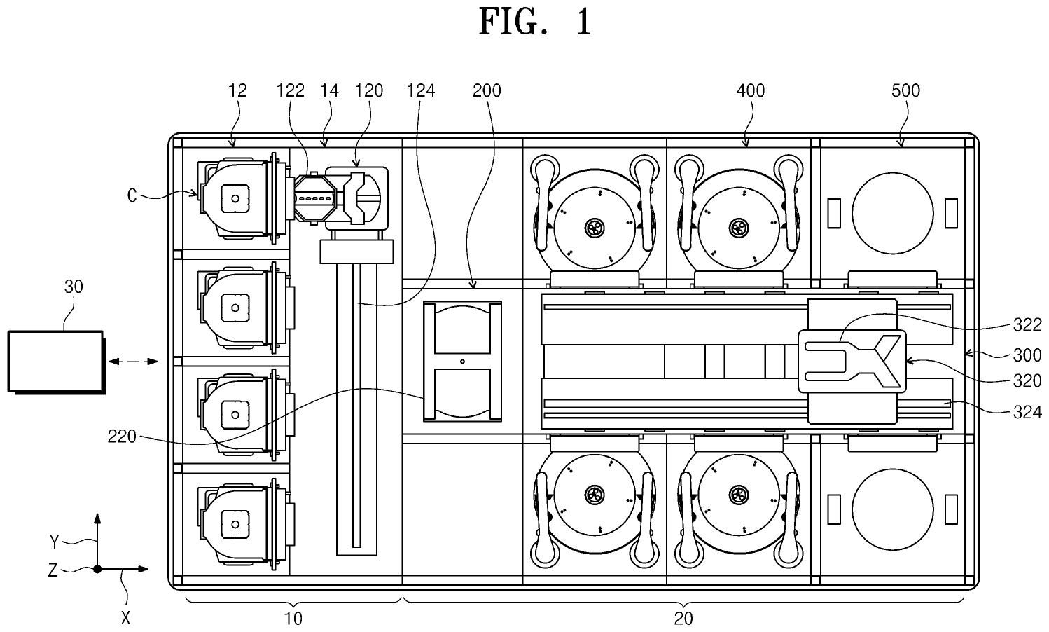

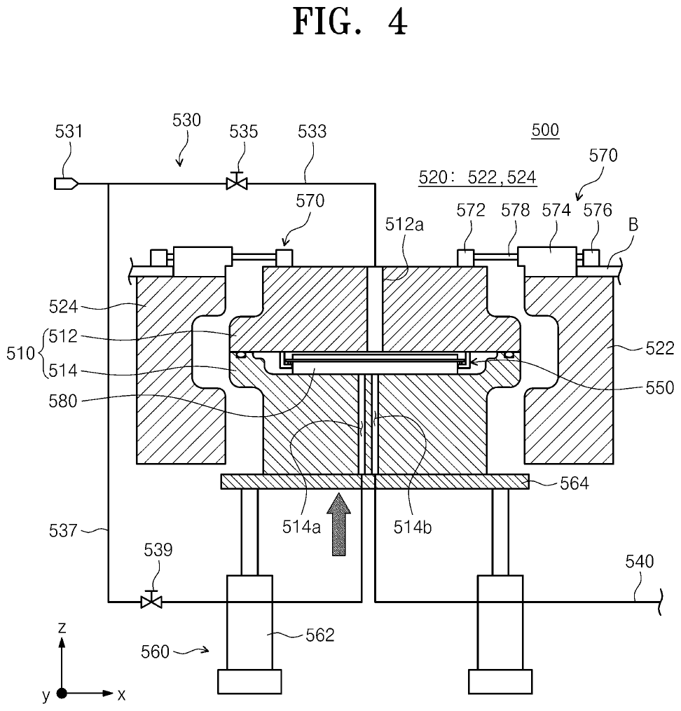

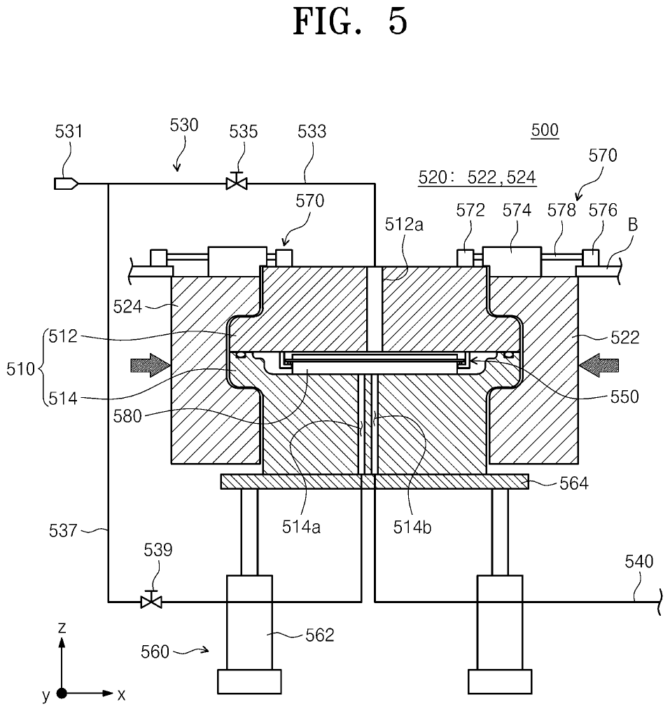

Hereinafter, an embodiment of the inventive concept will be described with reference to FIG. 1 to FIG. 13.

FIG. 1 illustrates a substrate treating apparatus according to an embodiment of the inventive concept.

Referring to FIG. 1, the substrate treating apparatus includes an index module 10, a treating module 20, and a controller 30. The index module 10 and the treating module 20 are disposed in a direction. Hereinafter, the direction in which the index module 10 and the treating module 20 are disposed will be referred to as a first direction X, a direction perpendicular to the first direction X will be referred to as a second direction Y, and a direction perpendicular to both the first direction X and the second direction Y will be referred to as a third direction Z.

The index module 10 transfers a substrate W from a container C in which the substrate W is stored to the treating module 20, and stores a substrate W to which a treating has been completed at the treating module 20 in the container C. A lengthwise direction of the index module 10 is provided in the second direction Y. The index module 10 has a load port 12 and an index frame 14. The index frame 14 is located between the load port 12 and the treating module 20. The container C in which the substrates W are stored is placed on the load port 12. A plurality of load ports 12 may be provided, and the plurality of load ports 12 may be disposed along the second direction Y.

For the container C, a sealed container such as a front open unified pod FOUP may be used. The container C may be placed on the load port 12 by a transfer means (not illustrated) such as an overhead transfer, an overhead conveyor, or an automatic guided vehicle or by an operator.

The index frame 14 is provided with an index robot 120. In the index frame 14, a guide rail 124 with its lengthwise direction in the second direction Y may be provided, and the index robot 120 may be provided to be movable along the guide rail 124. The index robot 120 may include a hand 122 on which the substrate W is placed, and the hand 122 may be forwardly and backwardly movable, rotatable around the third direction Z, and movable along the third direction Z. A plurality of hands 122 are provided to be spaced apart in an up/down direction, and the hands 122 may be forwardly and backwardly movable independently of each other.

The controller 30 may control the substrate treating apparatus. The controller may include a process controller e.g., a microprocessor (computer) that executes a control of the substrate treating apparatus, a user interface e.g., a keyboard in which an operator performs a command input operation or the like in order to manage the substrate treating apparatus, a display for visualizing and displaying an operation situation of the substrate treating apparatus, and the like, and a storage unit storing a control program for executing the process performed in the substrate treating apparatus under the control of the process controller, a various data and a program (i.e., treatment recipe) for executing various process in each component according to treating conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.

The treating module 20 includes a buffer unit 200, a transfer chamber 300, a liquid treating chamber 400, and a drying chamber 500. The buffer unit 200 provides a space in which the substrate W carried into the treating module 20 and the substrate W carried out from the treating module 20 temporarily stay. The liquid treating chamber 400 supplies a liquid onto the substrate W to perform a liquid treatment process of liquid treating the substrate W. The drying chamber 500 performs a drying process of removing a liquid remaining on the substrate W. The transfer chamber 300 transfers the substrate W between the buffer unit 200, the liquid treating chamber 400, and the drying chamber 500.

A lengthwise direction of the transfer chamber 300 may be provided in the first direction X. The buffer unit 200 may be disposed between the index module 10 and the transfer chamber 300. The liquid treating chamber 400 and the drying chamber 500 may be disposed on a side of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at an end of the transfer chamber 300.

According to an embodiment, the liquid treating chambers 400 may be disposed on both sides of the transfer chamber 300, the drying chambers 500 may be disposed on both sides of the transfer chamber 300, and the liquid treating chambers 400 may be disposed closer to the buffer unit 200 than the drying chambers 500. In some embodiments, at one and/or both sides of the transfer chamber 300, the liquid treating chambers 400 may be provided in an arrangement of A×B (A and B are natural numbers greater than 1 or 1) along the first direction X and the third direction Z. In some embodiments, at one and/or both sides of the transfer chamber 300, the drying chambers 500 may be provided in an arrangement of C×D (C and D are natural numbers greater than 1 or 1) along the first direction X and the third direction Z. In some embodiments, only liquid treating chambers 400 may be provided at one side of the transfer chamber 300, and only dry chambers 500 may be provided at the other side of the transfer chamber 300.

The transfer chamber 300 has a transfer robot 320. In the transfer chamber 300, a guide rail 324 with its lengthwise direction provided in the first direction X may be provided, and the transfer robot 320 may be provided to be movable on the guide rail 324. The transfer robot 320 may include a hand 322 on which the substrate W is placed, and the hand 322 may be provided to be forwardly and backwardly movable, rotatable around the third direction Z as an axis, and movable along the third direction Z. A plurality of hands 322 are provided to be spaced apart in the up/down direction, and the hands 322 may be forwardly and backwardly movable independently from each other.

The buffer unit 200 includes a plurality of buffers 220 on which the substrate W is placed. The buffers 220 may be disposed to be spaced apart from each other in the third direction Z. A front face and a rear face of the buffer unit 200 are opened. The front face is a surface facing the index module 10, and the rear face is a surface facing the transfer chamber 300. The index robot 120 may access the buffer unit 200 through the front face, and the transfer robot 320 may access the buffer unit 200 through the rear face.

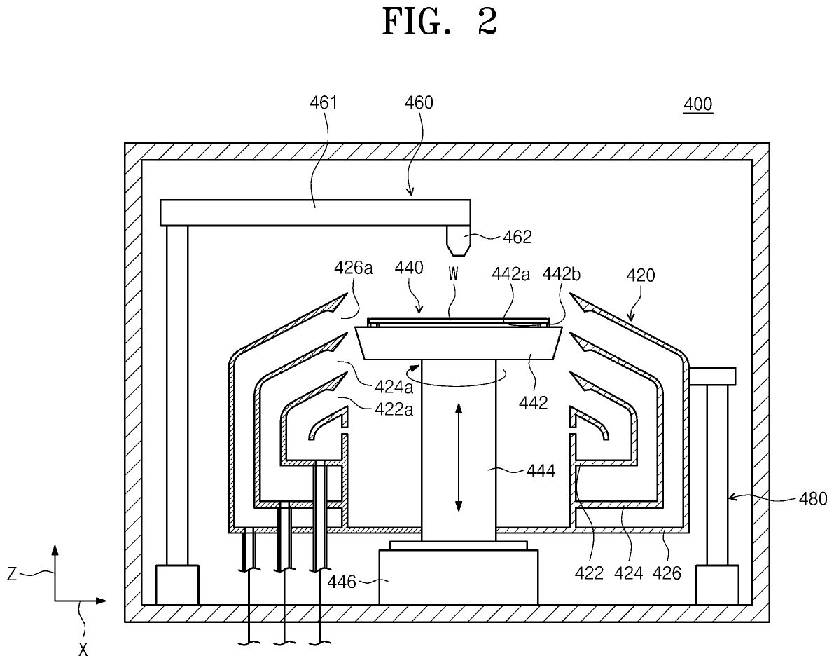

FIG. 2 schematically illustrates an embodiment of the liquid treating chamber of FIG. 1. Referring to FIG. 2, the liquid treating chamber 400 includes a housing 410, a cup 420, a support unit 440, a liquid supply unit 460, and a lifting/lowering unit 480.

The housing 410 may have an inner space in which the substrate W is treated. The housing 410 may have a generally hexahedral shape. For example, the housing 410 may have a rectangular parallelepiped shape. In addition, an opening (not shown) through which the substrate W is taken in or taken out may be formed in the housing 410. In addition, a door (not shown) for selectively opening and closing the opening may be installed at the housing 410.

The cup 420 may have a container shape with an open top. The cup 420 may have a treating space, and the substrate W may be liquid-treated in the treating space. The support unit 440 supports the substrate W in the treating space. The liquid supply unit 460 supplies the treating liquid onto the substrate W supported by the support unit 440. The treating liquid may be provided in a plurality of types and may be sequentially supplied onto the substrate W. The lifting/lowering unit 480 adjusts a relative height between the cup 420 and the support unit 440.

In an embodiment, the cup 420 has a plurality of recollecting containers 422, 424, and 426. Each of the recollecting containers 422, 424, and 426 has a recollecting space for recollecting the liquid used for substrate treatment. Each of the recollecting containers 422, 424, and 426 is provided in a ring shape surrounding the support unit 440. During a liquid treatment process, the treating liquid scattered by a rotation of the substrate W is introduced into the recollecting space through the inlets 422a, 424a, and 426a of each respective recollecting container 422, 424, and 426. According to an embodiment, the cup 420 has a first recollecting container 422, a second recollecting container 424, and a third recollecting container 426. The first recollecting container 422 is disposed to surround the support unit 440, the second recollecting container 424 is disposed to surround the first recollecting container 422, and the third recollecting container 426 is disposed to surround the second recollecting container 424. The second inlet 424a introducing the liquid into the second recollecting container 424 may be located above the first inlet 422a introducing the liquid into the first recollecting container 422, and the third inlet 426a introducing the liquid into the third recollecting container 424a may be located above the second inlet 424a.

The support unit 440 has a support plate 442 and a drive shaft 444. A top surface of the support plate 442 is provided in a substantially circular shape and may have a diameter larger than that of the substrate W. A support pin 442a is provided at a central part of the support plate 442 to support a bottom surface of the substrate W, and the support pin 442a is provided to protrude from the support plate 442 such that the substrate W is spaced apart from the support plate 442 by a predetermined distance. A chuck pin 442b is provided at an edge of the support plate 442. The chuck pin 442b is provided to upwardly protrude from the support plate 442, and supports a side of the substrate W so that the substrate W is stably held by the support unit 440 when the substrate W is rotated. The drive shaft 444 is driven by the driver 446, is connected to the center of the bottom surface of the substrate W, and rotates the support plate 442 based on its central axis.

According to an embodiment, the liquid supply unit 460 may include a nozzle 462. The nozzle 462 may supply the treating liquid to the substrate W. The treating liquid may be a chemical, a rinsing liquid, or an organic solvent. The chemical may be a chemical with strong acid properties or strong base properties. In addition, the rinsing liquid may be a deionized water. In addition, the organic solvent may be an isopropyl alcohol (IPA). In addition, the liquid supply unit 460 may include a plurality of nozzles 462, and each nozzle 462 may supply a different type of treating liquid. For example, one of the nozzles 462 may supply a chemical, another one of the nozzles 462 may supply the rinsing liquid, and still another one of the nozzles 462 may supply an organic solvent. In addition, the controller 30 may control the liquid supply unit 460 to supply the organic solvent from the still another one of the nozzles 462 to the substrate W after supplying the rinsing liquid to the substrate W from the another one of the nozzles 462. Accordingly, the rinsing liquid supplied onto the substrate W may be substituted with an organic solvent having a small surface tension.

The lifting/lowering unit 480 moves the cup 420 in the up/down direction. A relative height between the cup 420 and the substrate W is changed by an up/down movement of the cup 420. As a result, the recollecting containers 422, 424, 426 for recollecting the treating liquid are changed in accordance with a type of liquid supplied to the substrate W, so that the liquids can be recollected separately. Unlike the above description, the cup 420 is fixedly installed, and the lifting/lowering unit 480 may move the support unit 440 in the up/down direction.

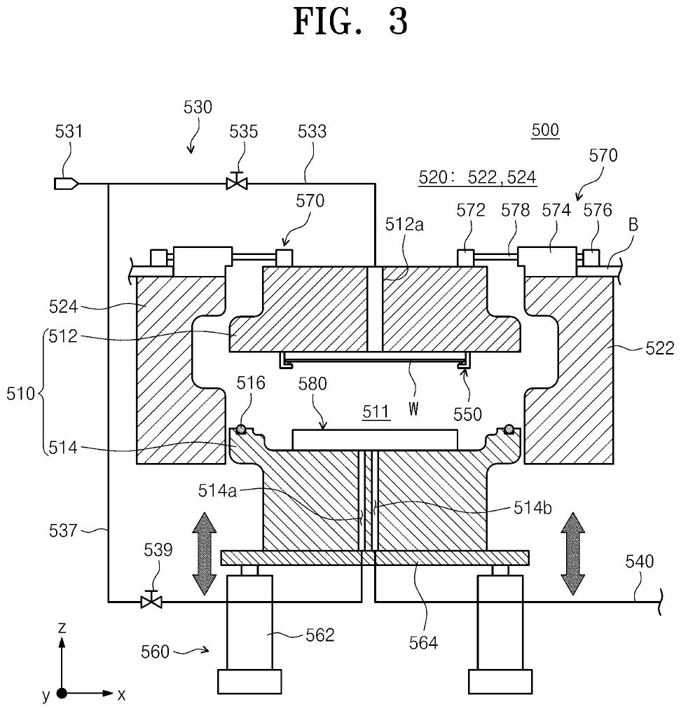

FIG. 3 schematically illustrates an embodiment of the drying chamber of FIG. 1.

Referring to FIG. 3, the drying chamber 500 according to an embodiment of the inventive concept may remove the treating liquid remaining on the substrate W by using the drying fluid in a supercritical state. For example, the drying chamber 500 may perform a drying process of removing an organic solvent remaining on the substrate W using the carbon dioxide CO₂ in a supercritical state.

The drying chamber 500 may include a chamber body 510 (an exemplary first body), a clamping body 520 (an exemplary second body), a fluid supply unit 530, a fluid exhaust line 540, a support member 550, a first moving unit 560, a second moving unit 570, and an anti-friction member 580. The chamber body 510 and the clamping body 520 may be collectively referred to as a body.

The chamber body 510 may include a top body 512 (another exemplary first body), and a bottom body 514 (another exemplary second body). The top body 512 and the bottom body 514 may be combined with each other to form a treating space 511. Any one of the top body 512 and the bottom body 514 may be configured to be relatively movable with respect to the other. For example, any one of the top body 512 and the bottom body 514 may be moved by a first moving unit 560. The first moving unit 560 may include a lifting/lowering driver 562 and a lifting/lowering plate 564. A plurality of lifting/lowering drivers 562 may be provided and connected to the lifting/lowering plate 564. The lifting/lowering plate 564 may be coupled to the bottom body 514. When the lifting/lowering driver 562 lifts and lowers the lifting/lowering plate 564, the bottom body 514 may also be lifted and lowered together with the lifting/lowering plate 564. A heater for heating a drying fluid supplied to the treating space 511 may be buried in the chamber body 510. In addition, when the top body 512 and the bottom body 514 are at a close position, a groove may be formed at the bottom body 514 to increase an airtightness of the inner space 511, and an O-ring 516 which is a sealing member may be inserted into the groove.

A position of the top body 512 may be fixed, and the bottom body 514 may be lifted and lowered in a third direction Z by the first moving unit 560. Hereinafter, a position where the bottom body 514 rises and contacts the top body 512 to form the treating space 511 is referred to as a close position, and a position where the bottom body 514 descends and is spaced apart from the top body 512 is referred to as an open position.

The clamping body 520 may include a first clamping body 522 and a second clamping body 524. The first clamping body 522 and the second clamping body 524 may clamp the chamber body 510 at opposite positions. An inner surface of the first clamping body 522 and the second clamping body 524 can have a shape substantially corresponding to an outer surface of the chamber body 510 in the close position. The first clamping body 522 and the second clamping body 524 may be moved by the second moving unit 570. A plurality of second moving units 570 may be provided. Any one of the second moving unit 570 may be connected to the top body 512 and the first clamping body 522, and the other of the second moving unit 570 may be connected to the top body 512 and the second clamping body 524.

The second moving unit 570 may include a first body 572 coupled to the top body 522, a second body 574 coupled to the clamping body 520 and moving along a moving rail 578, and a third body 576 coupled to a fixed outer wall B. The second body 574 may move the clamping body 520 in a direction toward the chamber body 510 while moving in the first direction X.

The fluid supply unit 530 may supply a drying fluid to the treating space 511. The drying fluid supplied by the fluid supply unit 530 may include a carbon dioxide CO₂. The fluid supply unit 530 may include a fluid supply source 531, a first supply line 533, a first supply valve 535, a second supply line 537, and a second supply valve 539.

The fluid supply source 531 may store and/or supply the drying fluid supplied to the treating space 511. The fluid supply source 531 may supply the drying fluid to the first supply line 533 and/or the second supply line 537. For example, a first supply valve 535 may be installed at the first supply line 533. In addition, the first supply line 533 may be connected to the first supply channel 512a formed at the top body 512. In addition, a second supply valve 539 may be installed at the second supply line 537. In addition, the second supply line 537 may be connected to the second supply channel 514a formed at the bottom body 514. The first supply valve 535 and the second supply valve 539 may be on/off valves. Depending on the on/off of the first supply valve 535 and the second supply valve 539, the drying fluid may selectively flow in the first supply line 533 or the second supply line 537.

In the above-described example, the first supply line 533 and the second supply line 537 are connected to one fluid supply source 531, but are not limited thereto. For example, a plurality of fluid supply sources 531 may be provided, the first supply line 533 may be connected to any one of a plurality of fluid supply sources 531, and the second supply line 537 may be connected to the other of the fluid supply sources 531.

In addition, the first supply line 533 may be a top supply line that supplies a drying gas from above the treating space 511. For example, the first supply line 533 may supply the drying gas to the treating space 511 in a direction from a top to a bottom. In addition, the second supply line 537 may be a bottom supply line that supplies the drying gas from below the treating space 511. For example, the second supply line 537 may supply drying gas to the treating space 511 in a direction from the bottom to the top.

The fluid exhaust line 540 may exhaust the drying fluid from the treating space 511. The fluid exhaust line 540 may be connected to a depressurizing member (not shown) that provides a depressurization to the treating space. In addition, the fluid exhaust line 540 may be connected to an exhaust channel 514b formed at the bottom body 514. The depressurizing member may be a pump. However, the inventive concept is not limited thereto, and the depressurizing member may be variously modified into a known device capable of providing a depressurization to the treating space.

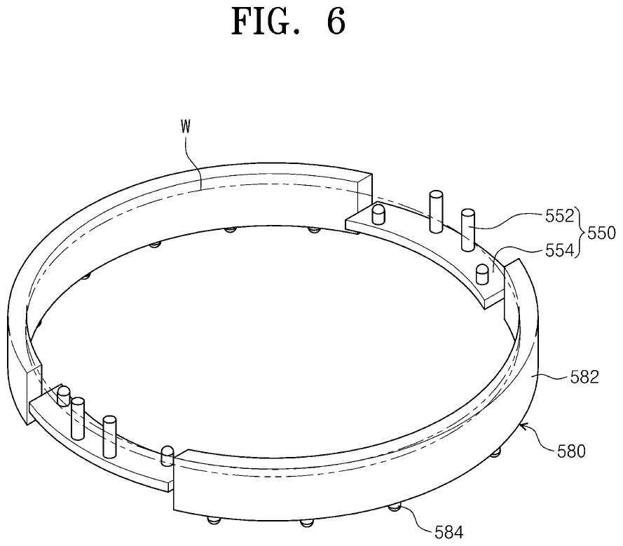

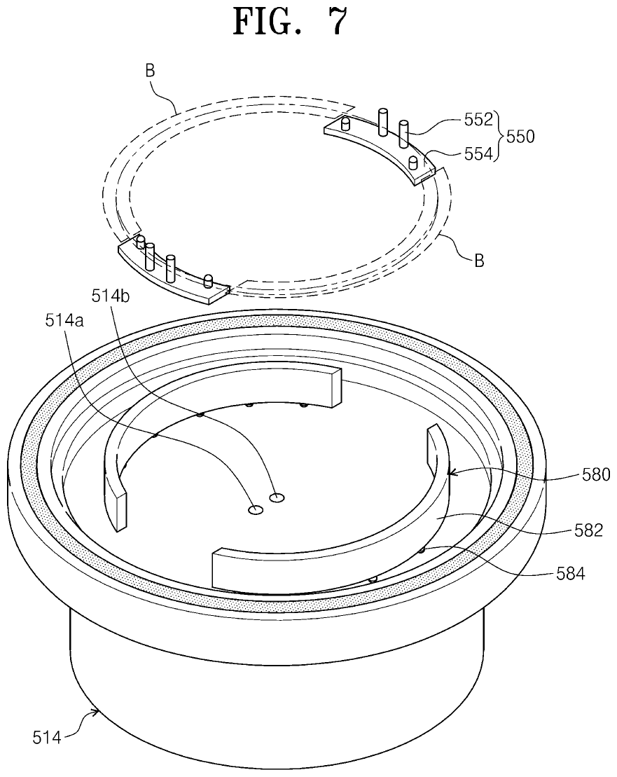

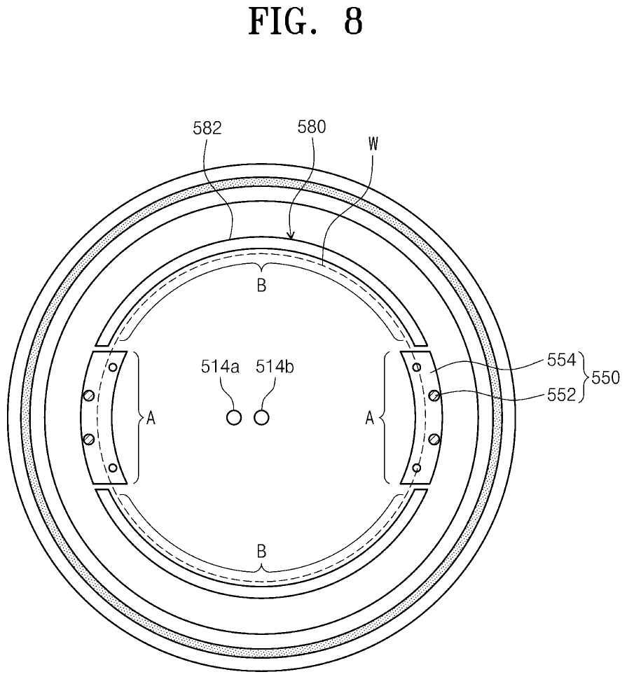

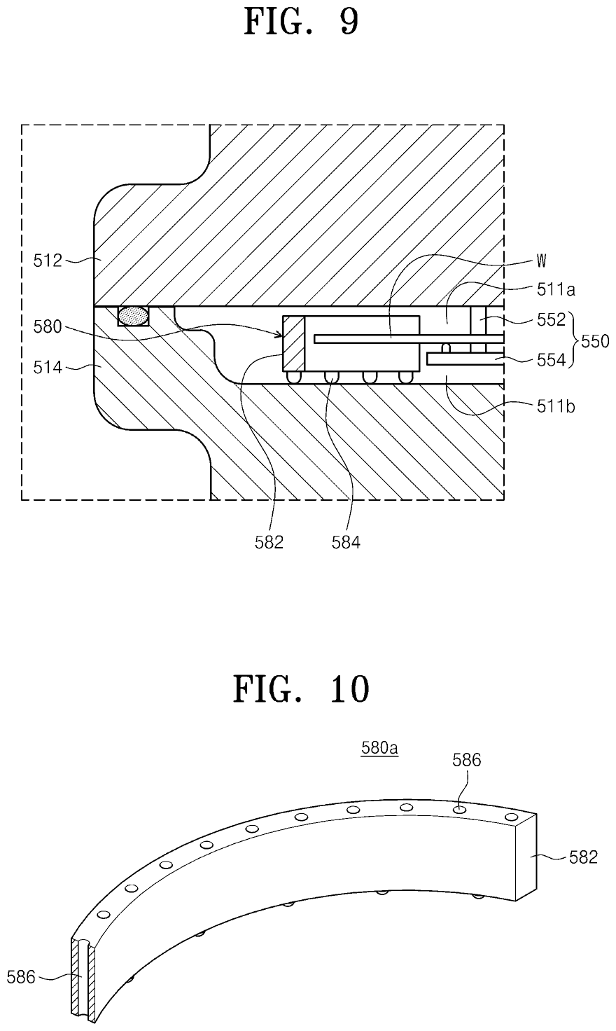

FIG. 6 is a perspective view to explain the support member and guide member of FIG. 3, FIG. 7 is a perspective view showing the guide member installed in the bottom body, FIG. 8 is a top view of the support member and guide member of FIG. 7, and FIG. 9 is an enlarged view of the support member and guide member of the top body and the bottom body are in a closed position.

Referring to FIG. 6 to FIG. 9, the support member 550 may support the substrate W such that a treating surface of the substrate W faces upward in the treating space 511. The support member 550 may support the first edge region A of the substrate W in the treating space 511. The support member 550 may support a bottom surface of the first edge region of the substrate W. The support member 550 may be installed on the top body 512.

In an embodiment, the support member 550 includes a fixing rod 552 and a holder 554.

The support member 550 may be symmetrically disposed on both sides with respect to the substrate. The fixing rods 552 may be provided in a bar shape downwardly extending from the bottom surface of the top body 512. A plurality of fixing rods 552 are provided. The holder 554 has an arc shape. The holder 554 extends in a direction perpendicular to the bottom end of the fixing rod 552. The holder 554 extends in the inner direction of the fixing rod 552.

The guide member 580 is provided to surround a periphery of the substrate supported by the support member 550. For example, the guide member 580 may be provided to surround the second edge region B of the substrate. Here, the second edge region B may be a region excluding the first edge region A. The guide member 580 includes a pair of guide blocks 582. The guide block 582 is supported by the bottom surface of the bottom body 514, and may be provided in an arc shape positioned outside the second edge region B when seen from above.

A passage through which a treating fluid passes may be provided between the guide block 582 and the top surface of the bottom body 514. That is, the guide block 582 may be provided to be spaced apart from the bottom body 514. To this end, the guide block may include support protrusions 584 on the bottom surface.

As shown in FIG. 8, the holder 554 and the guide block 582 have one ring shape when viewed from above.

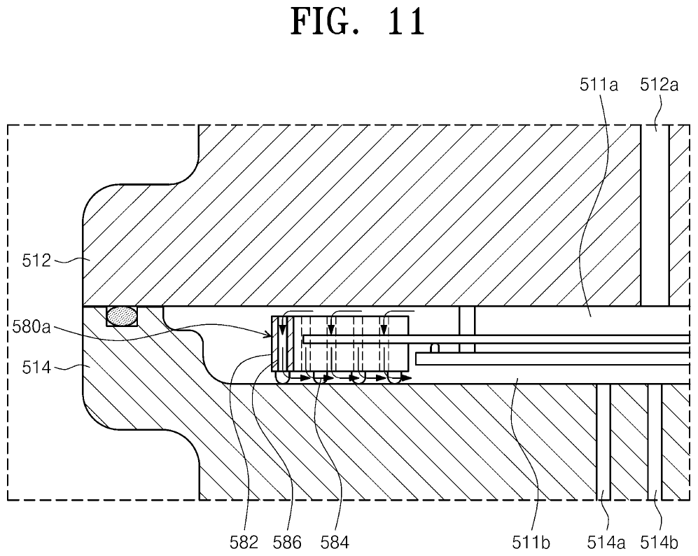

FIG. 10 is a partial cross-sectional perspective view showing a modified embodiment of the guide member, and FIG. 11 is a main part enlarged view showing the guide member in a state in which the top body and the bottom body are positioned at a closed position.

Referring to FIG. 10 and FIG. 11, the guide member 580a includes a guide block 582 and a support protrusion 584, and they are provided in a configuration and function generally similar to that of the guide block 582 and the support protrusion 584 shown in FIG. 6, and thus, a modified embodiment will be described focusing on a difference from the inventive concept.

In this modified example, the guide block 582 has through holes 586 through which the treating fluid passes. The through holes 586 may be provided at regular intervals. The through hole 586 is formed to penetrate from the top surface to the bottom surface of the guide block 582.

As such, the guide block 582 may be provided to allow the treating fluid to move between the top space 511a and the bottom space 511b of the treating space.

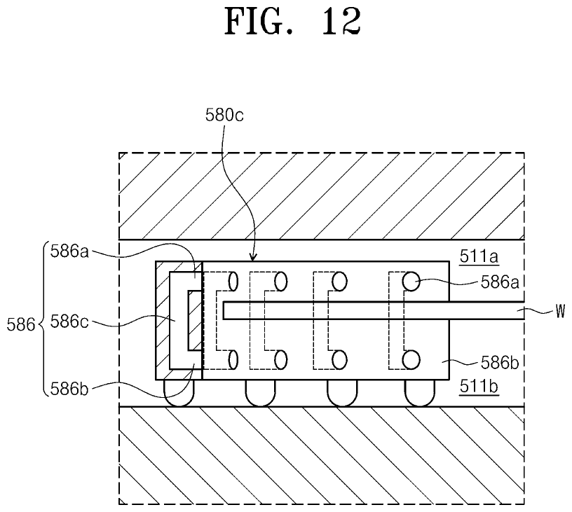

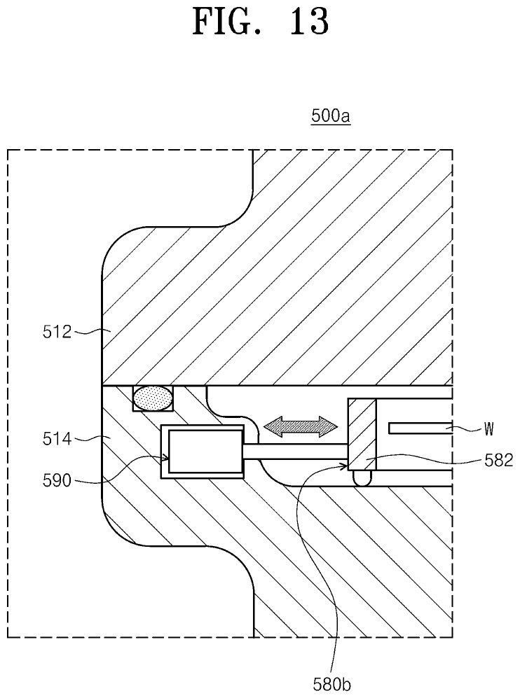

FIG. 12 is a view illustrating another modified embodiment of the guide block.

As illustrated in FIG. 12, the through hole 586 provided in the guide block 582 may include a first inlet 586a horizontally formed toward the top space 511a, a second inlet 586b horizontally formed to face the bottom space 51b, and a connection path 586c connecting the first inlet 586a and the second inlet 586b.

FIG. 13 is a view illustrating another embodiment of the inventive concept.

Referring to FIG. 13, the drying chamber 500a may further include a block driving unit 590. The block driving unit 590 may slide the guide block 582 to adjust a distance between the guide block 582 and the edge of the substrate W. A movement of the guide block 582 may be completed before a process treatment. In addition, the guide block 582 may be moved by the block driving unit 590 during the process treatment. That is, in a substrate drying process, a gap between the substrate W and the guide block 582 may be narrowed or widened.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber body having a top body and a bottom body which combine to provide a treating space therein;
a substrate support unit configured to support a substrate at the treating space;
a fluid supply unit configured to supply a treating fluid to the treating space;
a fluid exhaust line for exhausting the treating fluid from the treating space; and
a guide member provided to surround a periphery of the substrate supported by the substrate support unit.

2. The substrate treating apparatus of claim 1, wherein the substrate support unit supports a first edge region of the substrate at the treating space, and
the guide member is provided to surround a second edge region which is different from the first edge region of the substrate supported by the substrate support unit.

3. The substrate treating apparatus of claim 2, wherein the guide member includes a guide block in an arc shape supported by a bottom surface of the bottom body, and which is positioned at an outside of the second edge region when seen from above.

4. The substrate treating apparatus of claim 3, wherein the substrate support unit comprises:
fixing rods which are fixedly installed to a bottom surface of the top body to downwardly protrude from the bottom surface of the top body; and
a holder which extends in a horizontal direction with respect to the ground from a bottom end of the fixing rod, and which is provided to support a bottom surface of the first edge region of the substrate.

5. The substrate treating apparatus of claim 3, wherein the guide block includes support protrusions at a bottom surface to be spaced apart from the bottom surface of the bottom body.

6. The substrate treating apparatus of claim 5, wherein the guide block includes through holes which the treating fluid passes through.

7. The substrate treating apparatus of claim 6, wherein the treating space is divided into a top space and a bottom space with respect to the substrate supported by the substrate support unit, and
the guide block includes top surface positioned at the top space and a bottom surface positioned at the bottom space.

8. The substrate treating apparatus of claim 7, wherein the through hole comprises:
a first inlet connected to the top space;
a second inlet connected to the bottom space; and
a connection path connecting the first inlet and the second inlet.

9. The substrate treating apparatus of claim 3, wherein the guide block is provided to be spaced apart from an edge region of the substrate placed on the substrate support unit, and
further includes a block driving unit for sliding the guide block to adjust a gap between the guide block and the edge region of the substrate.

10. The substrate treating apparatus of claim 3, further comprising:
a lifting/lowering member for lifting and lowering any one of the top body and the bottom body with respect the other one to be spaced apart to an open position or a close position; and
a clamping unit configured to clamp the top body and the bottom body positioned at the close position.

11. The substrate treating apparatus of claim 3, wherein the treating space is divided into a top space and a bottom space with respect to the substrate supported on the substrate support unit, and
the top body includes:
a first supply channel connected to the fluid supply unit to supply the treating fluid to the top space, and
the bottom body includes:
an exhaust channel connected to the fluid exhaust line to exhaust the treating fluid from the treating space.

12. The substrate treating apparatus of claim 1, wherein the treating fluid is a supercritical fluid phase.

13. A substrate treating apparatus comprising:
a chamber body defining a treating space for treating a substrate, the chamber body including a first chamber body and a second chamber body provided below the first chamber body to be relatively movable with respect to the first chamber body;
a lifting/lowering member for lifting and lowering any one of the first chamber body and the second chamber body with respect to the other one to be spaced apart to an open position or a close position;
a clamping body for clamping the first chamber body and the second chamber body, if the first chamber body and the second chamber body are in close contact in a close position; and
a substrate support unit configured to support the substrate at the treating space;
a fluid supply unit configured to supply a treating fluid to the treating space;
a fluid exhaust line for exhausting the treating fluid from the treating space; and
a guide member provided to surround a periphery of the substrate which is supported by the substrate support unit.

14. The substrate treating apparatus of claim 13, wherein the substrate support unit supports a first edge region of the substrate at the treating space, and
the guide member is provided to surround a second edge region which is different from the first edge region of the substrate supported on the substrate support unit.

15. The substrate treating apparatus of claim 14, wherein the substrate support unit comprises:
fixing rods which are fixedly installed to a bottom surface of the first chamber body to downwardly protrude from the bottom surface of the first chamber body; and
a holder which extends in a horizontal direction with respect to the ground from a bottom end of the fixing rod, and which is provided to support a bottom surface of the first edge region of the substrate, and
the guide member includes a guide block in an arc shape supported by the second chamber body, and which is positioned at an outside of the second edge region when seen from above.

16. The substrate treating apparatus of claim 15, wherein a passage is provided between the guide block and the bottom surface of the second chamber body at which the treating fluid passes through.

17. The substrate treating apparatus of claim 15, wherein the guide block includes through holes which the treating fluid passes through.

18. The substrate treating apparatus of claim 15, wherein the treating space is divided into a top space and a bottom space with respect to the substrate supported by the substrate support unit, and
the through hole includes:
a first inlet connected to the top space;
a second inlet connected to the bottom space; and
a connection path connecting the first inlet and the second inlet.

19. A substrate treating apparatus for treating a substrate by using a treating fluid in a supercritical state, the substrate treating apparatus comprising:
a chamber body having a top body and a bottom body which combine to provide a treating space therein;
a substrate support unit configured to support the substrate at the treating space;
a lifting/lowering member for lifting and lowering any one of the top body and the bottom body with respect the other one to be spaced apart to an open position or a close position;
a clamping unit configured to clamp the top body and the bottom body positioned at the close position;
a fluid supply unit configured to supply the treating fluid to the treating space;
a fluid exhaust line for exhausting the treating fluid from the treating space; and
a guide block provided to surround a periphery of the substrate supported by the substrate support unit, and
wherein the substrate support unit is provided at the top body to support a first edge region of the substrate at the treating space, and
the guide member is provided to surround a second edge region which is different from the first edge region of the substrate supported by the substrate support unit.

20. The substrate treating apparatus of claim 19, wherein the guide block comprises:
support protrusions at a bottom surface of the guide block so that the treating fluid passes between the guide block and a bottom surface of the bottom body; and
through holes which the treating fluid passes through.
